(19) United States
(12) Patent Application Publication
(10) Pub. No.: US 2023/0327041 A1
(43) Pub. Date: Oct. 12, 2023

(54) MESA AVALANCHE PHOTODIODE WITH SIDEWALL PASSIVATION

(71) Applicant: NATIONAL RESEARCH COUNCIL OF CANADA, Ottawa (CA)

(72) Inventors: Oliver James PITTS, Ottawa (CA); Alexandre W. WALKER, Ottawa (CA)

(21) Appl. No.: 18/043,196

(22) PCT Filed: Aug. 27, 2021
(86) PCT No.: PCT/IB2021/057879

§ 371 Date: Feb. 27, 2023

Related U.S. Application Data
(60) Provisional application No. 63/071,533, filed on Aug. 28, 2020.

(51) Int. Cl. H01L 31/107; H01L 31/0304; H01L 31/0352; H01L 31/02

(52) U.S. Cl. CPC H01L 31/1075; H01L 31/03046; H01L 31/035281; H01L 31/02005

(57) ABSTRACT

A mesa-type avalanche photodiode comprising a first mesa of n-type material, a second mesa having an active region, and a third mesa of p-type material, wherein the second mesa includes a p-type sidewall formed by Zn diffusion for suppressing sidewall leakage current.

### FIELD

This specification relates generally to avalanche photodiodes (APDs), and in particular to a mesa avalanche photodiode with sidewall passivation employing Zn diffusion and method of manufacture thereof.

### BACKGROUND

Growth in high-capacity Ethernet systems, with their demands for low power and small size components, has led to renewed interest in high bandwidth APDs (see Masahiro Nada, Haruki Yokoyama, Yoshifumi Muramoto, Tadao Ishibashi, and Hideaki Matsuzaki, “50-Gbit/s vertical illumination avalanche photodiode for 400-Gbit/s Ethernet systems,” Opt. Express 22, 14681-14687 (2014)). The internal gain of APDs offers a potential advantage over PiN diode-based designs in detecting lower optical power signals (higher sensitivity), thus reducing overall system power requirements.

Design of a high speed APD requires mesa isolation of the active region to minimize parasitic capacitance. However, as the mesa sidewall intersects the high-field multiplication region, this results in high leakage current.

M. Nada et al. have demonstrated 50 Gbps performance of APDs using an “inverted p-down” architecture in which stepped mesa levels are used to limit the extent of the high electric field in the multiplication region to the area underneath the heavily doped contact layer (see M. Nada, Y. Yamada and H. Matsuzaki, “Responsivity-Bandwidth Limit of Avalanche Photodiodes: Toward Future Ethernet Systems,” in IEEE Journal of Selected Topics in Quantum Electronics, vol. 24, no. 2, pp. 1-11, March-April 2018, Art no. 3800811). A similar approach has been implemented in a wide-bandgap InAlAs reach-through structure, achieving sub-picoamp dark currents, where sidewall leakage current was mitigated using a Zn-diffused peripheral region of the mesa and a Ti-implanted guard ring and were based on a superlattice multiplication region, with a reported dark current of 0.36 μA at M=10 (see Yuan Yuan, Yabo Li, Joshua Abell, JiYuan Zheng, Keye Sun, Christopher Pinzone, and Joe C. Campbell, “Triple-mesa avalanche photodiodes with very low surface dark current,” Opt. Express 27, 22923-22929 (2019)).

U.S. Pat. No. 8,729,602 B2, “AVALANCHE PHOTODIODE”, T. Ishibashi et al., May 20, 2014, describes a triple-mesa design in which the extent of the high electric field is limited by a high-doped electrode buffer layer formed into a mesa of smaller diameter on top of the multiplication region mesa.

Various chemical treatments and passivation coatings are also known, such as: Chiu, S. Y., Chen, H. R., Chen, W. T., Hsu, M. K., Liu, W. C., Tsai, J. H. and Lour, W. S., 2008. Low-Dark-Current Heterojunction Phototransistors with Long-Term Stable Passivation Induced by Neutralized (NH4) 2S Treatment, Japanese Journal of Applied Physics, 47(1R), p. 35; Huang, R. T. and Renner, D., 1991. Improvement in dark current characteristics and long-term stability of mesa InGaAs/InP pin photodiodes with two-step SiN/sub x/surface passivation, IEEE photonics technology letters, 3(10), pp. 934-936; Teynor, W. A., Vaccaro, K., Buchwald, W. R., Dauplaise, H. M., Morath, C. P., Davis, A., Roland, M. A. and Clark, W. R., 2005. Cadmium sulfide passivation of InGaAs/InP mesa pin photodiodes, Journal of Electronic Materials, 34(11), pp. 1368-1372; “SUPERLATTICE AVALANCE PHOTODIODE”, I. Watanabe, Sep. 3, 1996, which discloses a superlattice avalanche photodiode design in which a Zn is performed to provide p-type doping of the mesa sidewall, which limits the extent of the high-field region to the interior of the mesa. A similar approach has been described for phototransistors (see M. Ogura et al., “Effects of Zn Doped Mesa Sidewall on Gain Enhanced InGaAs/InP Heterobipolar Phototransistor”, IEEE JOURNAL OF QUANTUM ELECTRONICS, VOL. 46, NO. 2, FEBRUARY 2010, p. 214).

Chemical treatments and passivation coatings, such as described in U.S. Pat. No. 8,729,602, have shown only limited success in suppressing sidewall leakage.

U.S. Pat. No. 5,552,629 specifically identifies the device as containing a multiplication region composed of a superlattice of alternating wide and narrow bandgap layers. In the implementations described, the heavily n-type doped contact layers are removed in a ring portion (necessary to avoid a high p-high n junction that would result in high leakage), so that the p-n junction reaches the surface at a thin etch stop layer directly above the high field multiplication layer. However, this architecture results in edge field enhancement requiring various means to counteract this effect, including regrowth of highly resistive material, implantation, or a buried mesa approach to limit the effective extent of the field control layer for avoiding edge breakdown. In addition to added fabrication complexity, these prior art approaches have the undesirable side effect of introducing additional defects into the device, with consequent deterioration of the leakage current and reliability characteristics.

Additional prior art includes Watanabe et al., “High-Speed, High-Reliability Planar-Structure Superlattice Avalanche Photodiodes for 10-Gb/s Optical Receivers”, JOURNAL OF LIGHTWAVE TECHNOLOGY, VOL. 18, NO. 12, DECEMBER 2000, p. 2200; Watanabe et al., “A New Planar-Structure InAlGaAs—InAlAs Superlattice Avalanche Photodiode with a Ti-Implanted Guard-Ring”, IEEE PHOTONICS TECHNOLOGY LETTERS, VOL. 8, NO. 6, JUNE 1996 821; Nada et al., “50-Gbit/s vertical illumination avalanche photodiode for 400-Gbit/s ethernet systems”, 2014; DOI:10.1364/OE.22.014681|OPTICS EXPRESS 14681 and U.S. Pat. No. 9,006,854 B2, “AVALANCHE PHOTODIODE”, T. Ishibashi et al., Apr. 14, 2015.

### SUMMARY

As discussed in detail below, a mesa avalanche photodiode is set forth with sidewall passivation employing Zn diffusion. In one embodiment, the APD includes an indium gallium arsenide (InGaAs) absorption layer, a triple-mesa architecture and a p-type sidewall with Zn diffusion for suppressing sidewall leakage. No implant process is employed in the design.

As discussed above, the prior art discloses p-type sidewalls for a high speed mesa APDs and Zn diffused sidewalls for reducing sidewall leakage for superlattice-APDs and heterobipolar phototransistors, as well as processes to terminate the charge sheet (Ti implantation, etching). However, this specification discloses Zn diffused sidewall applied to a high bandwidth APD design consisting, in one embodiment, of a single multiplication layer without any further steps required to restrict the charge sheet, and with the p-n junction terminating at the surface in a low-doped layer (similar to planar devices).

Additional aspects include a dual charge sheet with a low doped spacer wherein the spacer and upper charge sheet are not removed around the periphery of the lower mesa—instead, the Zn doped sidewall continues upward along the periphery of these layers. Thus, the high-field multiplication layer is not exposed at the surface.

In another aspect, a mesa isolated APD is described having a low n-type (non-intentionally doped) electron transit layer, and with field control layers of opposite doping type above and below the multiplication layer. A high-doped and narrow bandgap contact layer is provided for the purpose of reducing the contact resistance of the metal electrodes formed on the semiconductor surface, with a contact buffer layer of intermediate bandgap between the contact layer and the electron transit layer.

Zn diffusion is performed to create a p-type region encompassing the mesa sidewalls. The high field region is thus confined to the interior of the mesa, except where it reaches the top surface of the semiconductor layers, inhibiting leakage along the mesa sidewalls. The asymmetric p++/n− junction is similar to that employed in planar devices and serves to minimize leakage current at the mesa top surface. Furthermore, the multiplication layer can be a single layer of wide bandgap material to minimize tunneling current. Regrowth and/or implantation are not necessary in this design: edge field enhancement does not occur.

Therefore, according to an aspect of the present specification, an avalanche photodiode is set forth comprising a first mesa of n-type material having a first diameter; a second mesa having an active region having a second diameter greater than the first diameter; and a third mesa of p-type material having a third diameter greater than the second diameter; wherein the second mesa includes a p-type sidewall formed by Zn diffusion for suppressing sidewall leakage current.

According to another aspect, there is provided a method of manufacturing the avalanche photodiode as set forth above, comprising a first mesa etch performed by wet etching in H2SO4:H2O2:H2O; a second mesa etch using a Cl-based inductively coupled plasma etch followed by a selective etch in HCl:H3PO4 stopping at the top of the p-type grading layer; a third mesa etch using Cl-based inductively coupled plasma etch; and deposition of n- and p-ohmic contact metal electrodes by evaporation and liftoff of Pd/Ge/Ti/Pt/Au and Pd/Zn/Pd/Au/Ti, respectively.

### BRIEF DESCRIPTION OF DRAWINGS

Implementations are described with reference to the following figures, in which:

FIG. 1A is a top view of a mesa avalanche photodiode, according to an embodiment.

FIG. 1B is a cross section view through the mesa avalanche photodiode of FIG. 1A.

FIG. 1C is a cross section view through the mesa avalanche photodiode of FIG. 1A, according to an alternative embodiment.

FIG. 2 is a graph showing dark I-V curves for (a) a mesa avalanche photodiode without a Zn-diffused sidewall, and (b) a mesa avalanche photodiode according to an embodiment, with the inside edge of the Zn diffusion inside the mesa sidewall.

FIG. 3 is a plot showing averages of dark current across the mesa avalanche photodiode of FIGS. 1A and 1B measured at 20 V reverse bias as a function of different mesa radii based on statistical variation measured across the wafer.

### DETAILED DESCRIPTION

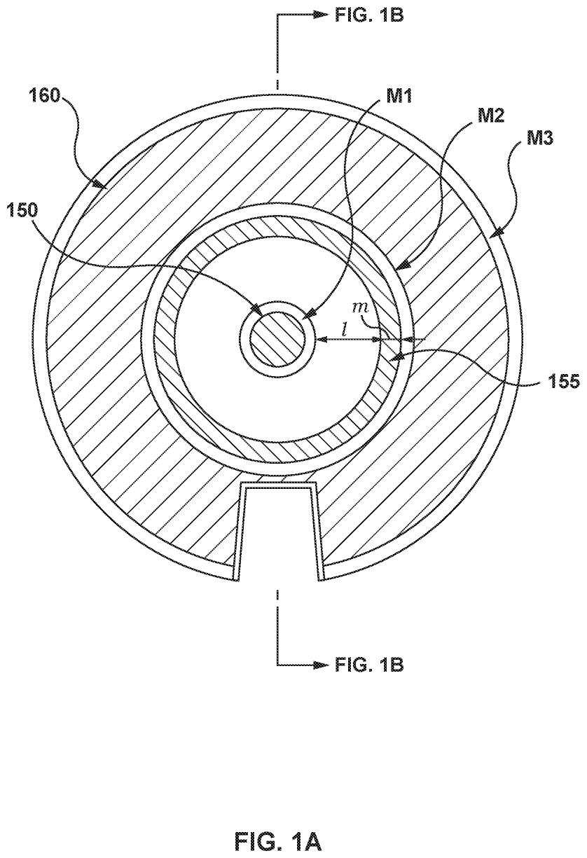

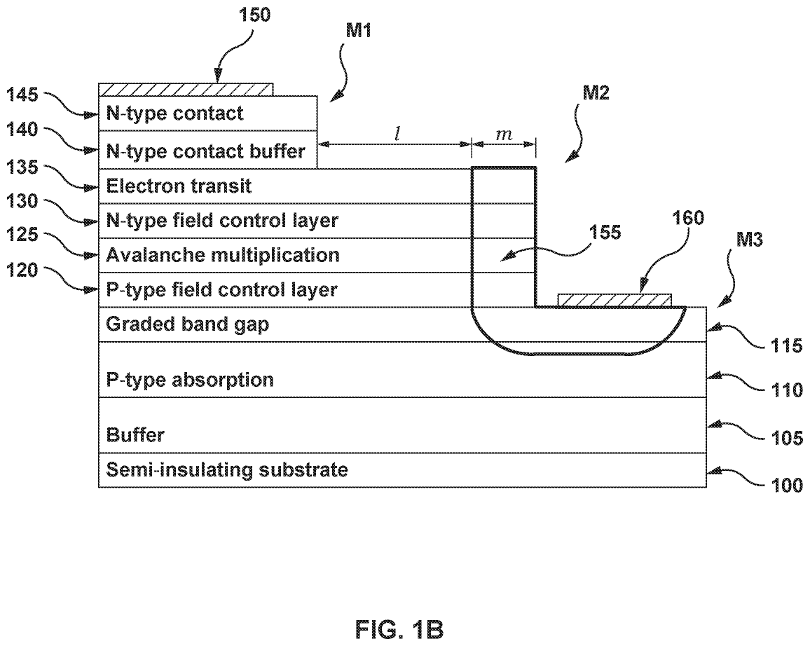

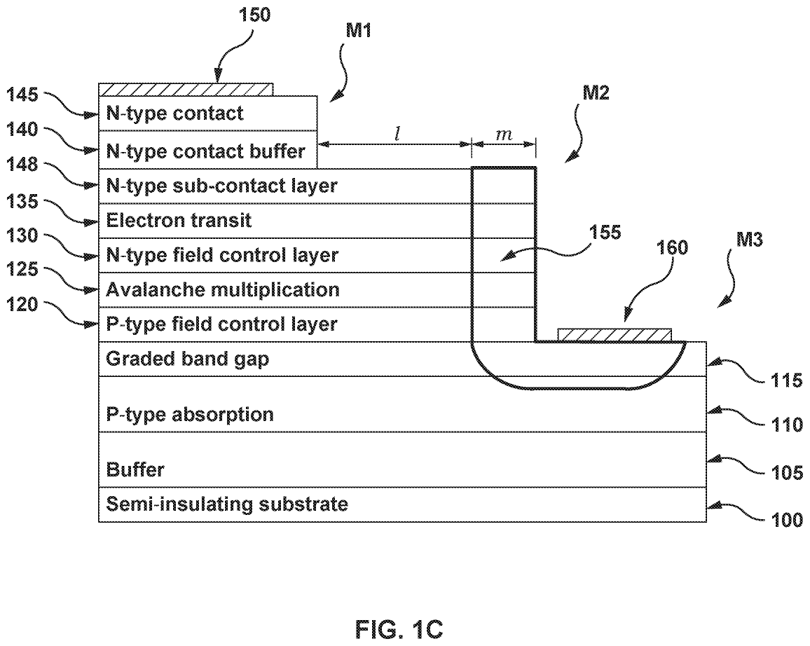

A schematic diagram of the APD epitaxial structure according to an embodiment, is shown in FIGS. 1A and 1B, comprising a semi-insulating substrate 100 onto which is deposited buffer layer 105, P-type light absorption layer 110 for absorbing photons passing through the substrate 100 and buffer layer 105, a graded band gap layer 115, p-type field control layer 120, avalanche multiplication layer 125 and n-type field control layer charge sheet 130 that, in conjunction with p-type field control layer 120 controls the electric field in the avalanche multiplication layer 125. A low n-type (non-intentionally doped) electron transit layer 135 is grown on top of the n-type field control layer 130, followed by an n-type intermediate bandgap contact buffer layer 140 and a high-doped and narrow bandgap n-type contact layer 145 above the buffer layer 140 for reducing the contact resistance of a metal electrode 150. Illumination of the APD takes place from the bottom through substrate 100.

In an embodiment, the thickness of field buffer layer 105 is 300 nm of InP, the avalanche multiplication layer 125 is 80 nm and the light absorption layer 110 is 600 nm of InGaAs, of which the first 200 nm is intentionally Zn-doped, as discussed below. A first mesa M1 is formed in the n-type doped buffer layer 140 and narrow bandgap contact layer 145, followed by a second mesa M2 containing the non-intentionally doped electron transit layer 135, n-type field control layer 130, avalanche multiplication layer 125 and p-type field control layer 120. A third mesa etch (M3) extends through the p-type graded band gap layer 115, p-type light absorption 110 and buffer 105 layers into the semi-insulating substrate 100.

A patterned Zn diffusion is performed after the first mesa M1 etch to form a p-type Zn doped region 155 on the sidewall of the second mesa M2 once etched. The Zn diffusion results in a heavily doped region at the surface of the step-graded layer 115 outside the second mesa M2, which is used to form an ohmic p-contact with metalized electrode 160.

A lateral offset l is provided between the first mesa M1 and Zn diffusion 150, and an offset m is provided between the Zn diffusion and the second mesa M2 sidewall.

Thus, the first mesa M1 and third mesa M3 form n-type and p-type APD elements with the M2 avalanche region therebetween. As shown best in FIG. 1A, the third mesa M3 forms a p-type ring that circumscribes the M2 sidewall edge. The mesa structure positions the PN junction on the top surface of the device for enhanced passivation.

In an embodiment, the first mesa M1 etch was performed by wet etching in H2SO4:H2O2:H2O, while the second mesa M2 etch employed a Cl-based inductively coupled plasma (ICP) etch followed by a selective etch in HCl:H3PO4 stopping at the top of the step graded layer 115. The third mesa M3 was formed by Cl-based ICP etching. Standard photolithography was use for patterning, and Pd/Ge/Ti/Pt/Au and Pd/Zn/Pd/Au/Ti were deposited by evaporation and liftoff for the n- and p-ohmic contact metal electrodes 150 and 160, respectively.

Numerical device simulations of the APD structure depicted in FIGS. 1A and 1B were performed using a semiconductor modeling software suite, which showed the highest electric field located underneath the first mesa M1, with the field at the sidewall of the second mesa M2 being around ˜ 1/1000 of the maximum field, indicating that p-type sidewall doping in conjunction with the stepped mesa structure is effective at reducing the sidewall field with no field enhancement at or near the edge of the device, indicating that no additional methods (such as, e.g., an implanted guard ring) are required to suppress edge breakdown.

According to the alternative embodiment depicted in FIG. 1C, an additional an n-type doped, wide band gap sub-contact layer 148 is provided above layer 135 and extending to the edge of the second mesa M2, for extending the high field region across areas where the contact layers are removed, while retaining the advantage of a very low field in the p-type sidewall region as in the embodiment of FIG. 1B. The embodiment of FIG. 1C also permits a ring contact and top illumination of device.

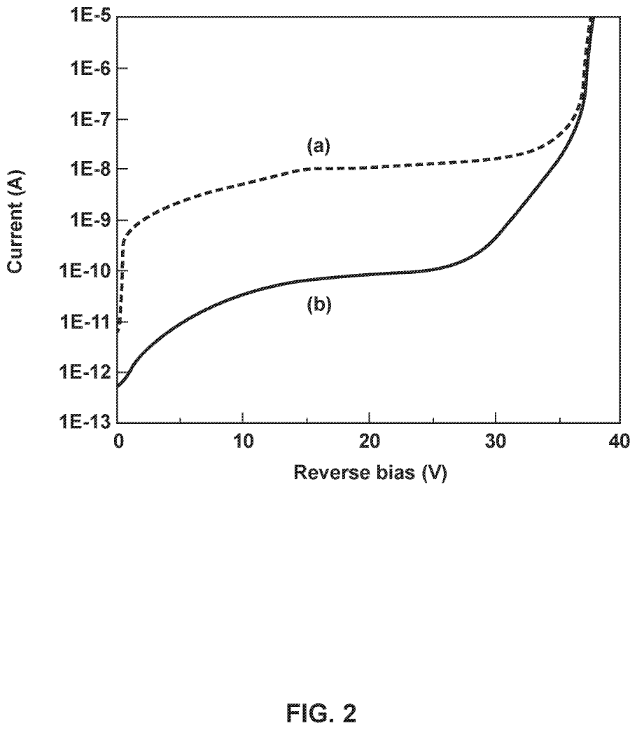

Suppression of surface leakage by the p-type sidewall design was verified experimentally by comparing room temperature dark current-voltage (I-V) curves of devices with and without the Zn diffusion extending into the mesa sidewall. FIG. 2 shows dark I-V curves for two 30 μm diameter devices in the same area of the wafer; (a) without a Zn-diffused sidewall, and (b) with the inside edge of the Zn diffusion mask 2 μm inside the mesa sidewall (m=2 μm). At low reverse bias, up to around 25 V, the dark current of the device with Zn diffused sidewalls is seen to be two orders of magnitude lower than the device without the Zn diffusion extending into the mesa sidewall. In this region the sidewall leakage is expected to be the dominant contribution. Above 25 V, the dark current of the Zn diffused sidewall device begins to increase more steeply, likely due to tunneling in the thin (80 nm) multiplication layer 125. This latter dark current component would be expected to be similar for the device without the Zn diffusion extending into the mesa sidewall, but does not become the dominant component until a higher reverse bias is reached, as is apparent from the change in slope in curve (a) above 30 V.

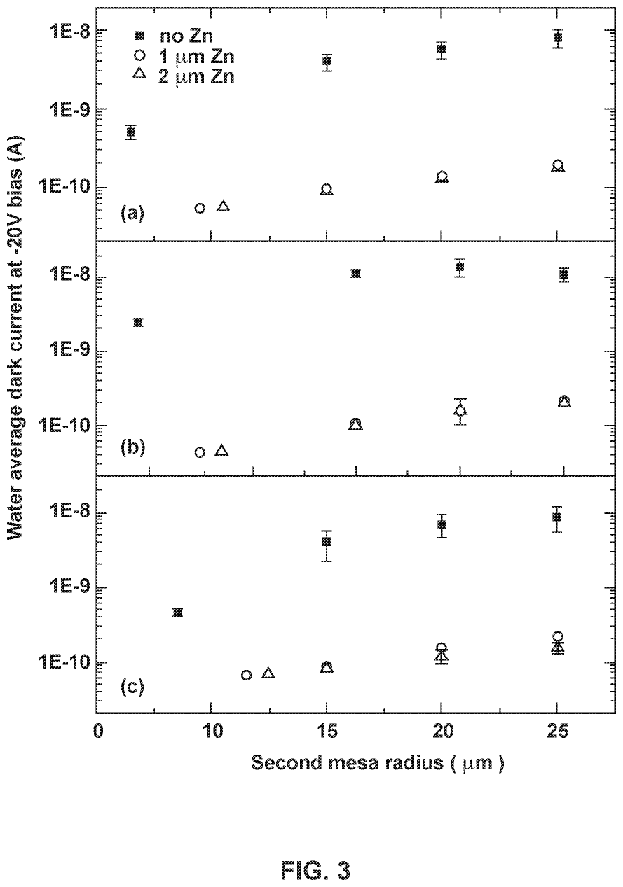

To verify that suppression of the sidewall leakage current is consistent in devices across the wafer, 32 wafer sites were sampled, with a set of devices with variations of the second mesa M2 radius and the offset parameters m and l measured at each site. Devices exhibiting early breakdown or high dark current (>1 μA) at low bias were excluded from averaging. FIG. 3 shows the wafer averages of dark current measured at 20 V reverse bias as a function of the second mesa radius for (a) l=6 μm, (b) l=4 μm, and (c) fixed first mesa M1 diameter of 5 μm, where error bars indicate standard deviation of sites across the wafer. A strong reduction of dark current for the Zn doped sidewall devices with m=1 μm and m=2 μm, compared to the reference devices without Zn doped sidewalls, was observed for all three sets. The reduction in dark current averaged over wafer locations is greatest for the l=4 μm set, reaching a factor of ˜100.

The scope of the claims should not be limited by the embodiments set forth in the above examples, but should be given the broadest interpretation consistent with the description as a whole.

1. An avalanche photodiode comprising:
a first mesa of n-type material having a first diameter;
a second mesa having an active region having a second diameter greater than the first diameter; and
a third mesa of p-type material having a third diameter greater than the second diameter;
wherein the second mesa includes a p-type sidewall formed by Zn diffusion for suppressing sidewall leakage current.

2. The avalanche photodiode of claim 1, wherein the first mesa comprises an n-type contact buffer layer and a high-doped and narrow bandgap contact layer above the contact buffer layer for reducing contact resistance of a metal electrode formed on the surface thereof.

3. The avalanche photodiode of claim 2, further including a window in the narrow bandgap contact layer for top-side illumination, thereby avoiding parasitic absorption of incident light before it reaches the active region.

4. The avalanche photodiode of claim 1, wherein the active region of the second mesa comprises field control layers of opposite doping type above and below a high-field avalanche multiplication layer.

5. The avalanche photodiode of claim 4, wherein the second mesa further includes an electron transit layer, and wherein the p-type sidewall formed by Zn diffusion extends upward along the periphery of the electron transit layer and field control layers for confining the high-field avalanche multiplication layer to the interior of the second mesa, except where it reaches the top surface, thereby inhibiting leakage along the mesa sidewalls.

6. The avalanche photodiode of claim 5, wherein the high-field avalanche multiplication layer comprises a single layer of wide bandgap material to minimize tunneling current.

7. The avalanche photodiode of claim 1, wherein the third mesa comprises a semi-insulating substrate onto which is deposited a p-type buffer layer, p-type absorption layer and p-type graded band gap layer, and wherein the Zn diffusion extends through the graded band gap layer and in to the absorption layer.

8. The avalanche photodiode of claim 1, wherein a lateral offset l is provided between the first mesa and Zn diffusion, and a further offset m is provided between the Zn diffusion and a sidewall of the second mesa.

9. The avalanche photodiode of claim 8, wherein the third mesa forms a p-type ring that circumscribes the sidewall of the second mesa.

10. The avalanche photodiode of claim 2, wherein the n-type contact buffer layer of intermediate bandgap is fabricated from indium gallium arsenide phosphide (InGaAsP) and the high-doped and narrow bandgap contact layer is fabricated from indium gallium arsenide (InGaAsP).

11. The avalanche photodiode of claim 5, wherein the low doped electron transit layer, high-field avalanche multiplication layer, upper and lower field control layers are fabricated from Indium Phosphide (InP).

12. The avalanche photodiode of claim 7, wherein the p-type light absorption layer and p-type graded band gap layer are fabricated from indium gallium arsenide (InGaAsP).

13. The avalanche photodiode of claim 1, further including an n-type doped, wide band gap sub-contact layer above the electronic transit layer and extending to the edge of the second mesa.

14. A method of manufacturing the avalanche photodiode of claim 7, comprising:
a first mesa etch performed by wet etching in H2SO4:H2O2:H2O;
a second mesa etch using a Cl-based inductively coupled plasma etch followed by a selective etch in HCl:H3PO4 stopping at the top of the p-type grading layer;
a third mesa etch using Cl-based inductively coupled plasma etch; and
deposition of n- and p-ohmic contact metal electrodes by evaporation and liftoff of Pd/Ge/Ti/Pt/Au and Pd/Zn/Pd/Au/Ti, respectively.
